(19) United States
(12) Patent Application Publication
(10) Pub. No.: US 2026/0086147 A1
(43) Pub. Date: Mar. 26, 2026

(54) CHIPLET TESTING WITH LOWER SPEED INTERFACE

(71) Applicant: Intel Corporation, Santa Clara, CA (US)

(72) Inventors: Nikhil Krishna Gopalakrishna, San Jose, CA (US); Jing Zhang, Folsom, CA (US); Srinivasan Rajappa, Folsom, CA (US)

(21) Appl. No.: 18/894,791

(22) Filed: Sep. 24, 2024

(51) Int. Cl. G01R 31/317; G01R 31/3181

(52) U.S. Cl. CPC G01R 31/31713; G01R 31/31813

(57) ABSTRACT

Embodiments herein relate to testing chiplets during the manufacturing process. In one aspect, an on-chiplet interface is provided which allows testing of inter-chiplet communications of a chiplet on a package substrate without requiring the use of another chiplet. The interface communicates with an external Field-Programmable Gate Array (FPGA) on the package substrate at a reduced frequency compared to a frequency of the inter-chiplet communications. The FPGA can in turn communicate with a workstation to receive instructions and provide test results. The FPGA sends test pattern signals to, and evaluates corresponding responses from, circuitry of the chiplet which implements an inter-chiplet communication standard such as the Universal Chiplet Interconnect Express (UCIe) standard. In another aspect, the physical layer (PHY) circuits of two chiplet are tested with respective FPGAs.

### BACKGROUND

Integrated circuit devices can include a number of chiplets arranged in a package, where the chiplets have different functions and may be fabricated using different technologies. A chiplet architecture can have advantages in terms of performance and power, lower manufacturing costs and greater flexibility and scalability. However, various challenges are presented in testing the chiplets during the manufacturing process.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 depicts an example package 100 having different chiplets, in accordance with various embodiments.

FIG. 2 depicts an example description of the Universal Chiplet Interconnect Express (UCIe) standard, in accordance with various embodiments.

FIG. 3 depicts an example test setup 300 for a first use case involving an alternate testing path for a chiplet, in accordance with various embodiments.

FIG. 4A depicts an example system 400 for the first use case, in accordance with various embodiments.

FIG. 4B depicts an example implementation of the Field-Programmable Gate Array (FPGA) 320 of FIG. 4A, in accordance with various embodiments.

FIG. 5A depicts a first part of an example system 500 for the first use case, in accordance with various embodiments.

FIG. 5B depicts a second part of the example system 500 of FIG. 5A, in accordance with various embodiments.

FIG. 6 depicts an example test setup 600 for a second use case involving PHY testing of a chiplet, in accordance with various embodiments.

FIG. 7 depicts an example system 700 for the second use case, in accordance with various embodiments.

FIG. 8 depicts an example system 800 for the second use case, in accordance with various embodiments.

FIG. 9 illustrates an example of components that may be present in a computing system 950 for implementing the techniques (e.g., operations, processes, methods, and methodologies) described herein.

### DETAILED DESCRIPTION

As mentioned at the outset, various challenges are encountered in testing chiplets.

A chiplet is a small, modular chip that forms part of a larger integrated circuit (IC) or system. Instead of creating a single, large monolithic chip, manufacturers can design multiple smaller chiplets, each performing a specific function, and then integrate them into a single package. A chiplet is a type of a die. Chiplets allow for a modular approach to chip design, where different functions (such as central processing unit (CPU), graphics processing unit (GPU), memory controller, I/O, signal processing unit, etc.) are separated into individual chiplets. Also, chiplets can be fabricated using different process technologies optimized for their specific functions. Other benefits include scalability, reduced cost, and power efficiency.

The chiplets within a package can communicate with one another through high-speed interconnects using standards such as Universal Chiplet Interconnect Express (UCIe) and Advanced Interface Bus (AIB). In some cases, this inter-chiplet communication tests the interconnects. However, during the manufacturing process, including testing of the chiplets before they are released to the end user, chiplets for a package may not be ready at the same time. Accordingly, the testing of a given chiplet can be delayed.

On any chiplet that uses an inter-chiplet communication protocol, validation of the silicon (chiplet) typically involves either waiting for another compatible chiplet to be added to the package or performing a loopback test. A loopback test confirms that a transceiver or port of a chiplet is functioning properly by connecting the transmitter and receiver of the same module. However, this only validates the physical layer protocol.

The solutions provided herein address the above and other issues. In one aspect, the solution validates the link and protocol layers of an inter-chiplet communication protocol by providing a general-purpose input-output (GPIO)-based interface, referred to herein as a raw die-to-die interface (RDI) circuit, on a chiplet. The interface can operate at a lower speed (frequency) than the interconnect standard, to provide compatibility with an external control circuit such as a Field-Programmable Gate Array (FPGA) chip. The FPGA can, in turn, communicate with a workstation to receive instructions and provide test results. The FPGA sends test pattern signals to, and evaluates corresponding response signals from, circuitry of the chiplet which implements the inter-chiplet communication standard.

The solution can include a digital interface circuit that reduces the speed of the UCIe RDI layer, in the case of the UCIe standard, for example, which typically runs at 1-2 Ghz. The circuit includes lower speed GPIOs that runs at 100-200 Mhz, for instance. This speed reduction utilizes the properties of the UCIe standard definition of the RDI layer. The solution does not disturb or modify the existing path between two chiplets through the UCIe physical layer (PHY), and provides an alternate path in the UCIe stack for the purpose of validation.

The PHY layer can refer, e.g., to the layer responsible for the physical aspects of communication between chiplets within a package. This includes the transmission and reception of data over the physical medium, which is typically on the interconnects/wires connecting the chiplets. The PHY manages signal integrity, clocking and timing, voltage/current levels, link initialization and training, and error detection and correction.

In another aspect, the RDI circuit bypasses the PHY layer and allows the link/logic layer to communicate with the FPGA, so that the PHY layer circuits are not tested with the FPGA.

The solutions provide a number of advantages, including facilitating the validation of chiplets which are manufactured for various products in a standalone manner. It saves time and costs and avoids delays. The solutions also help to perform a debugging process for protocol layers used in the products without having to depend on the physical layer intellectual property (IP) of the communication protocol.

The solution can involve adding more GPIOs to use as an RDI circuit interface, or re-purpose other functional GPIOs for the chiplet package to use as an RDI circuit.

These and other features will be further apparent in view of the following discussion.

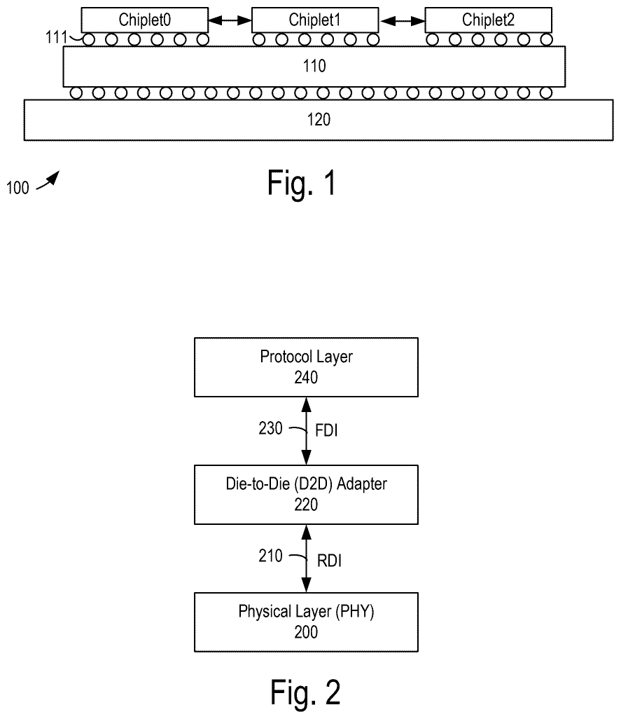

FIG. 1 depicts an example package 100 having different chiplets, in accordance with various embodiments. As mentioned, a number of chiplets can be arranged in a package. In this example, Chiplet0, Chiplet1 and Chiplet2 are arranged on a package substrate 110 which in turn is arranged on a printed circuit board (PCB) 120. The chiplets and package may be mounted using ball grid arrays, for example, as depicted by the circles 111. The arrows between the chiplets represent communications between the chiplets using the UCIe or other standard. The communication can occur via conductive paths in the package substrate 110. Conductive paths also extend from the chiplets to the PCB. The collection of chiplets in the package may be referred to as a system in package (SiP).

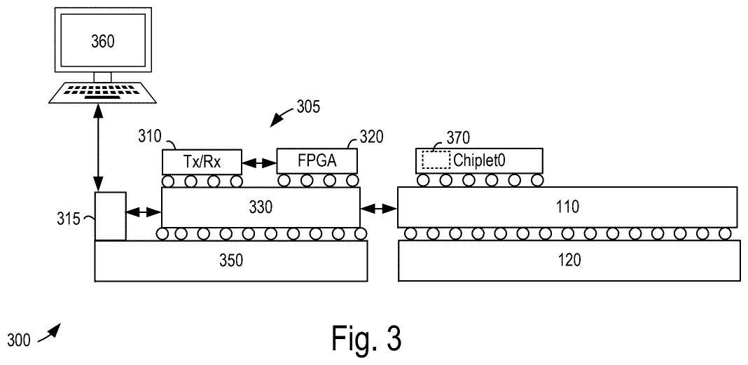

FIG. 2 depicts an example description of the Universal Chiplet Interconnect Express (UCIe) standard, in accordance with various embodiments. The interconnect standard includes a physical layer (PHY) 200, a raw die-to-die interface (RDI) 210, a die-to-die (D2D) adapter 220, a flit-aware D2D interface (FDI) 230, and a protocol layer 240.

The PHY layer provides for functions such as electrical signaling, link training, lane repair, lane reversal, scrambling/descrambling, sideband signaling (training and transfers), analog front end and clock forwarding (clocking).

The RDI is a functional block that provides a data interface between two chiplets in the same package. The RDI can include a controller that provides a seamless connection between the internal interconnect fabric on two dies/chiplets. The RDI can be implemented using a high-speed serializer/deserializer (SerDes) architecture or high-density parallel architecture,

The die-to-die (D2D) adapter provides functions such as arbitration (ARB)/multiplexing (MUX), cyclic redundancy check (CRC)/retry, link state management, and parameter navigation. Thus, it provides link state management and parameter negotiation between chiplets, and optional support for additional data reliability safeguards via CRCs and link-level retries.

The flit-aware D2D interface may be a 256 byte Flow Control Unit (FLIT) that handles the actual data transfer. A flit, or flow control unit or digit, is a unit of data that is split into smaller pieces when a packet is transmitted over a link.

The protocol layer can involve standardized protocols such as UCIe, PCI-Express (PCIe) and Compute Express Link (CXL), which is built on top of PCIe. UCIe, for example, covers the die-to-die I/O physical layer, die-to-die protocols, software stack, and compliance testing. UCIe is an open standard for die-to-die interconnects. While UCIe is discussed, other standards could be used.

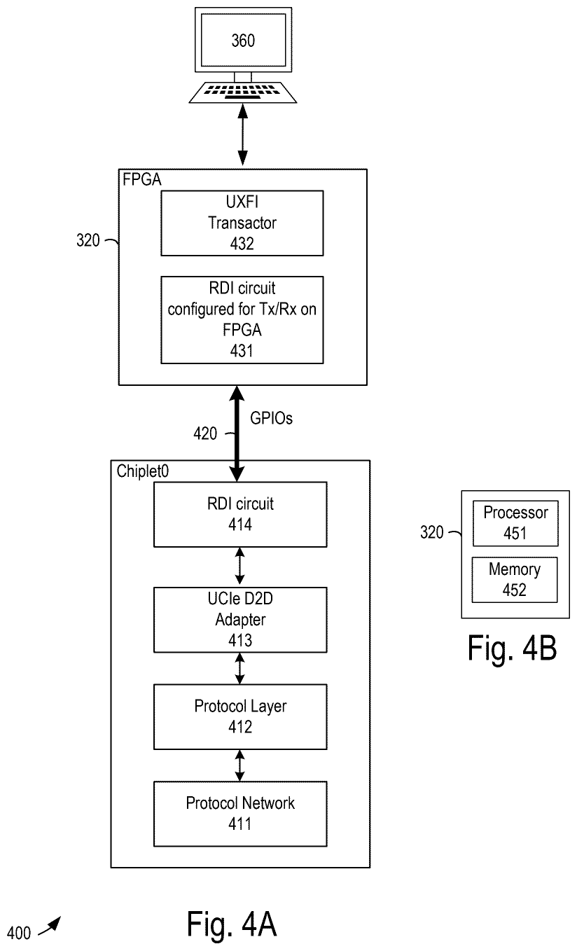

FIG. 3 depicts an example test setup 300 for a first use case involving an alternate testing path for a chiplet, in accordance with various embodiments. The test set up modifies the test setup of FIG. 1 by depicting only one chiplet, Chiplet0, on the first package substrate 110. The chiplet includes an added circuit 370 which interfaces with the FPGA to enable testing as described herein.

As mentioned, when only one chiplet is present on the package substrate, the inter-chiplet interconnects cannot be tested by the chiplets themselves. Similarly, this problem arises when other chiplets are present on the package substrate but cannot be used for testing due to defects or other issues.

The test setup further includes a Field-Programmable Gate Array (FPGA) chip 320 and Tx/Rx chip 310 (a transmitter/receiver or transceiver chip) on a second package substrate 330 of a package 305. The FPGA is on a separate PCB 350. Generally, the FPGA can be on a separate chassis than the chiplet and can connect to the chiplet under test using cables. The FPGA and transceiver may communicate with one another and with the PCB 350 via the ball grid arrays. For example, the transceiver may send data to and receive data from a computer 360 (e.g., laptop, desktop, workstation or server) via a port 315 such as a Universal Serial Bus (USB) port or a Peripheral Component Interconnect Express (PCIe) bus port.

An FPGA is a reprogrammable integrated circuit that contain an array of programmable logic blocks that can be configured and connected to perform different functions. It has input/output blocks (IOBs) that allows it to interface with external devices. An FPGA stores its configuration information in re-programmable media, such as flash memory or static RAM (SRAM), so it can be changed after it is programmed. The FPGA is used in this example to communicate with Chiplet0, which is the chiplet under test. For example, the FPGA can communicate test patterns and evaluate the replies by the chiplet to validate the functioning of the interconnect standard at the chiplet. The FPGA is in a separate package than the chiplet in this example. A single FPGA could potentially be used to test multiple chiplets.

Note the use of an FPGA to control the chiplet testing is one example as other types of external control circuits, external to the chiplet and the chiplet package, could be used as well.

Also, while the FGPA is in a different package substrate than the chiplet, it could be on the same PCB, for instance. The FPGA could also be on a separate chassis, connecting to the chiplet under test using cables.

The circuit 370 allows the chiplet to interface with the FPGA to send/receive data to validate the functioning of the interconnect standard at the chiplet. The FPGA can work in conjunction with software running on the computer 360. The FPGA can translate instructions (such as to generate test pattern signals) from the computer 360 to a format which can be understood by the chiplet. For example, the software may be provided according to a high-level code such as C and translated into data which is compatible with Advanced eXtensible Interface (AXI), an on-chip communication bus protocol. Similarly, for communications in the other direction, the FPGA can translate AXI data to a format compatible with the software.

Generally, the first use case addresses the problem of designing an integrated circuit device where a pair of chiplets is needed to ensure that the communication between the chiplets is working. However, in the manufacturing environment, various issues arise such that the likelihood of getting two chiplets to interconnect properly at the first tape-out is low. Since the communication is chiplet-to-chiplet (or inter-chiplet), the micro-bumps of the chiplet package and the associated electrical paths do not allow external access to the interconnect circuits via the pins on the package. The first use case addresses this scenario.

The solutions allows testing of a single chiplet without requiring it to communicate with another chiplet. This will expedite post-silicon testing of the chiplet package without waiting for multiple chiplets to be installed on the package in a working state.

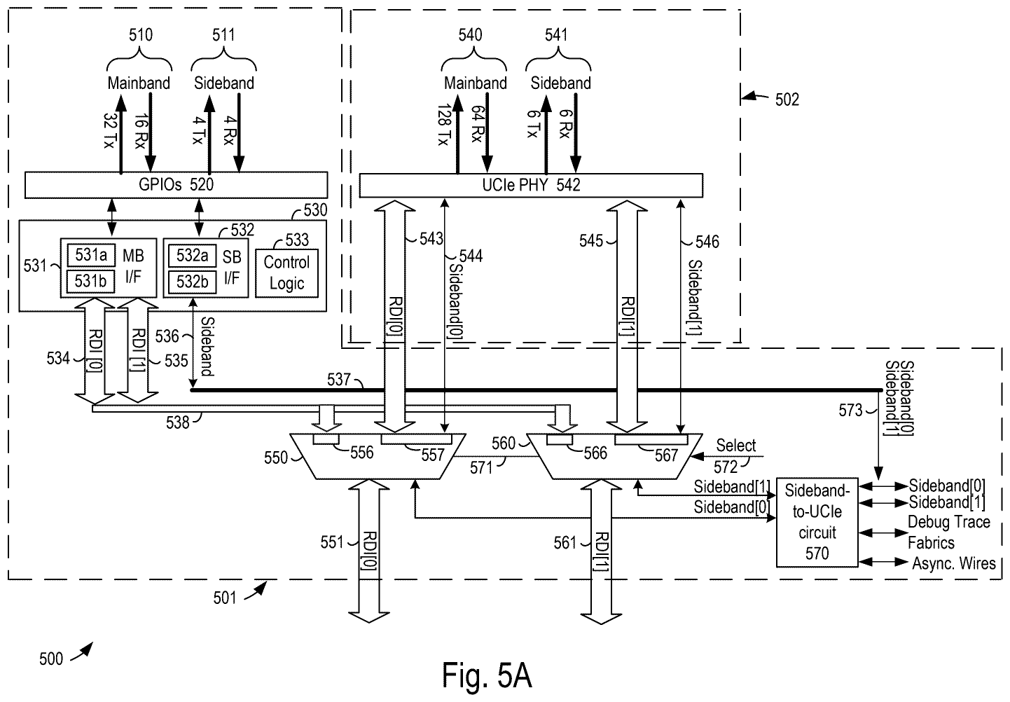

FIG. 4A depicts an example system 400 for the first use case, in accordance with various embodiments. The system includes a chiplet, e.g., Chiplet0, configured to implement an inter-chiplet interconnect standard such as UCIe. The chiplet can include a protocol network circuit 411, a protocol layer circuit 412, a UCIe D2D adapter 413 and an RDI interface circuit 414. The chiplet communicates with the FPGA 320 via a GPIO interface 420. A GPIO interface can include uncommitted digital signal pins on an integrated circuit or electronic circuit board which may be used as an input or output, or both, and are controllable by software. The FPGA essentially provides an alternate testing path for the chiplet.

The FPGA includes an RDI circuit 431 configured for Tx/Rx on the FPGA, and a Universal eXchange For Interfaces (UXFI) transactor 432. The FPGA is coupled to the computer 360 to receive instructions and report test results during the test process. The FIFO can be asynchronous and control the RDI interface throttling using the ready signal of the standards specification while operating at a lower speed than the chiplet interconnect standards specification. The transactor, or transaction-level interface, can be implemented in software and refer to a component or module that acts as an interface between different parts of a system, translating data and protocols between two domains, e.g., a domain of the FPGA and a domain of the chiplet. The transactor can be considered to be a control logic circuit. For example, the transactor can be used to translate instructions from the computer 360 to a format which can be understood by the chiplet, and to translate instructions from the chiplet to a format which can be understood by the computer 360.

UXFI is a protocol for interfacing different components, typically in electronic design automation (EDA) or system-on-chip (SoC) verification environments. UXFI converts high-level transactions, such as data transfers or control signals, into the specific format and timing required by the UXFI protocol, and vice versa. A UXFI transactor can be implemented in software and has a number of functions. For example, the UXFI transactor translates high-level operations into the specific UXFI protocol signals required by the components it interfaces with. For instance, it might convert a read or write request into UXFI protocol signals that can be understood by the chiplet. The transactor manages the flow of transactions, ensuring that data is sent and received according to the timing and control requirements of the UXFI protocol, including handling handshaking, data integrity, and synchronization.

While the UXFI transactor is discussed as an example, other types of transactors can be used as well.

In an example implementation, the transactor 432 is used with the computer 360 which may run a SystemC model of a chiplet to drive the traffic to/from the chiplet. SystemC is a C++-based modeling language that can be used to create models of central processing units (CPUs). It has an event-driven simulation interface that allows designers to simulate concurrent processes using C++ syntax. SystemC processes can communicate in a simulated real-time environment using signals from C++, the SystemC library, or user-defined signals. SystemC is often used for electronic system-level design and transaction-level modeling. With the transactor 432, the FPGA can run the model in cooperation with the computer 360.

The transactor can translate test pattern signals from a format compatible with software running on the computer 360 to a format compatible with the chiplet, and translate the responses from the format compatible with the chiplet to the format compatible with the computer.

The RDI circuit 414, e.g., RDI circuit, provides an interface between the slower speed GPIOs and the higher speed RDI circuit 431. As mentioned, as an example, the GPIO interfaces can be operated in the range of about 100 to about 200 Mhz, e.g., +/−10%, and the original RDI interface in the test chiplet can operate at about 1 to about 2 Ghz for mainband and about 100 MHz to 400 MHz for sideband, which is used for configuration of the mainband.

The RDI circuit 414 has two primary functions. A first function is reducing the speed of the chiplet such that it can be captured or driven by the FPGA GPIO interface 420. The second function is to drive the UCIe RDI signals to the D2D adapter 413 such that the D2D adapter can be re-used without having to interface with a real UCIe PHY. The UCIe D2D adapter can include a state machine that is kept in a logically correct state during the transmission of data through the circuit.

FIG. 4B depicts an example implementation of the FPGA 320 of FIG. 4A, in accordance with various embodiments. The FPGA includes a memory 452 to store instructions for execution by a processor 451 to provide the functions described herein.

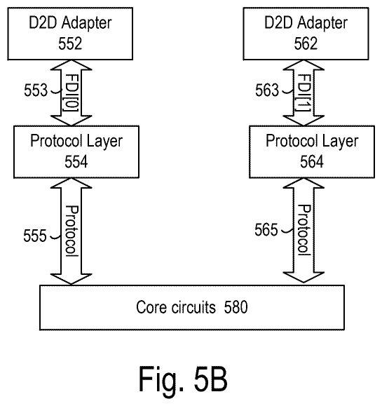

FIG. 5A depicts a first part of an example system 500 for the first use case, in accordance with various embodiments. The system 500 includes a circuit 501 that generally corresponds to the RDI circuit 414 and GPIO interface 420 of FIG. 4A, and the circuit 370 of FIG. 3. The circuit 501 can be considered to be a bridge or interface circuit that is used to communicate on one side with the FPGA and on the other side with the D2D adapters 552 and 562, protocol layer circuits 554 and 564, and the core circuits 580 of the chiplet (FIG. 5B), for testing. The remaining components are a circuit 502 of the chiplet for communicating with other chiplets which may not be present during the testing. In one approach, the circuit 502 is not active/used when the FPGA is communicating with the chiplet during testing of the chiplet, and the circuit 501 is not used at other times.

The circuit 501 includes GPIOs 520 which are coupled to transmit/receive via mainband (in-band) signal paths 510 (e.g., 32 transmit and 16 receive paths) and sideband signal paths 511 (e.g., 4 transmit and 4 receive paths) to communicate with the FPGA on one side of the GPIOs. On an opposing side, the GPIOs communicate with a mainband I/F circuit 531 (MB I/F) and a sideband I/F circuit 532 (SB I/F) which operate according to control logic 533 in an interface circuit 530 (corresponding to the RDI circuit 414 or RDI circuit). The mainband I/F circuit 531 transmits/receives mainband data RD[0] and RD[1] on paths 534 and 535, respectively, which are coupled via a path 538 to multiplexers 550 and 560. The sideband I/F circuit 532 transmits/receives sideband data, sideband[0] and sideband[1], on paths 536, 537 and 573 to a sideband-to-UCIe circuit 570. The two data paths RD[0] and RD[1] are provided according to the UCIe protocol specification. There can be multiple instances of the RDI circuit in a device, with a pair of data paths for each RDI circuit. In theory, one or more data paths can be provided.

The interface circuit 530 is to down convert (reduce) a frequency of the test pattern signals received from the FPGA and upconvert (increase) a frequency of the response signals received from the D2D adapters. For example, the mainband I/F circuit 531 can include a down conversion circuit 531a and an up conversion circuit 531b, and the sideband I/F circuit 532 can include a down conversion circuit 532a and an up conversion circuit 532b.

The multiplexers 550 and 560 are RDI selection multiplexers. The multiplexer 550 has first and second inputs 556 and 557, respectively, and the multiplexer 560 has first and second inputs 566 and 567, respectively. The multiplexers select one of the two inputs based on a selection signal, Select, on paths 572 and 571. Specifically, to make the circuit 501 active and the circuit 502 inactive, the inputs 556 and 566 are selected to pass RD[0] and RD[1] on paths 534 and 535 to paths 551 and 561, respectively. To make the circuit 502 active and the circuit 501 inactive, the input 557 at the multiplexer 550 is selected to pass RD[0] and Sideband[0] data on paths 543 and 544, respectively, to the path 551. Also, the input 567 at the multiplexer 560 is selected to pass RD[1] and Sideband[1] data on paths 545 and 546, respectively, to the path 561.

The sideband-to-UCIe circuit 570 includes input/output paths for sideband data, debug trace fabrics and asynchronous wires.

The paths 543-546 are coupled to a UCIe PHY 542 which can communicate with other chiplets to transmit/receive via mainband (in-band) signal paths 540 (e.g., 128 transmit and 64 receive paths) and sideband signal paths 541 (e.g., 6 transmit and 6 receive paths).

FIG. 5B depicts a second part of the example system 500 of FIG. 5A, in accordance with various embodiments. The paths 551 and 561 in FIG. 5A are coupled to D2D adapters 552 and 562, corresponding, e.g., to the UCIe D2D adapter 413 of FIG. 4A. The D2D adapters 552 and 562 are coupled to protocol layer circuits 554 and 564 (corresponding, e.g., to the protocol layer circuit 412 of FIG. 4A), respectively, by paths 553 and 563, respectively, as data FD[0] and FD[1], respectively. The protocol layer circuits 554 and 564 are coupled to one or more core circuits 580 of the chiplet by paths 555 and 565, respectively, by a protocol corresponding, e.g., to the protocol network circuit 411 of FIG. 4A.

The one or more core circuits 580 refer, e.g., to circuits which implement the main function of the chiplet, e.g., CPU, GPU, memory controller, I/O, signal processing unit, etc.

As mentioned, the circuit 501 can operate at a lower frequency than the circuit 502, e.g., half the frequency or less, to accommodate the frequency of the FPGA.

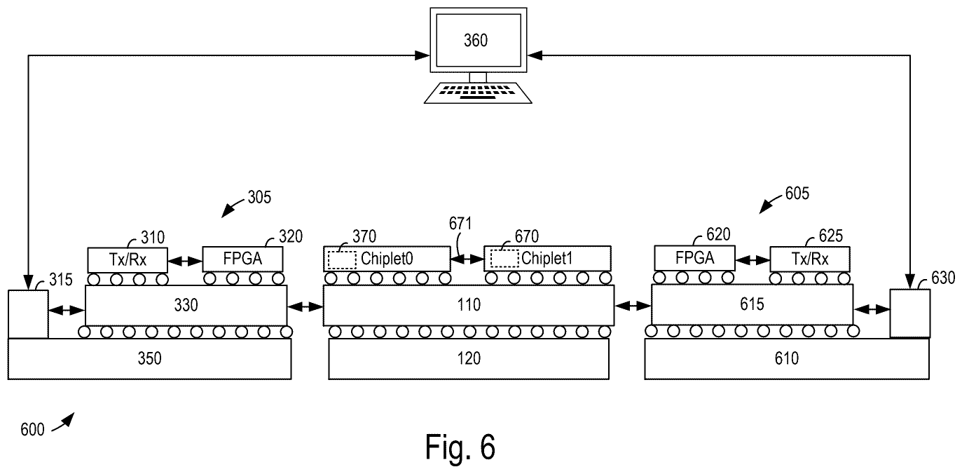

FIG. 6 depicts an example test setup 600 for a second use case involving PHY testing of a chiplet, in accordance with various embodiments. This use case allows testing of the PHY circuit such as the UCIe PHY circuit 542 of FIG. 5A for a pair of chiplets. The testing advantageously does not require the presence or use of the D2D adapter, physical layer circuits and/or core circuits of the chiplet. In this case, the package substrate 110 includes Chiplet1 with an interface circuit 670 in addition to Chiplet0 with its interface circuit 370. The interface circuits 370 and 670 can be the same.

The setup further includes the package 305 for communicating with Chiplet0 and a corresponding package 605 for communicating with Chiplet1. The package 605 includes a package substrate 615 on a PCB 610. On the package substrate 615, an FPGA 620 communicates with the interface circuit 670 as well as with a transceiver 625. The transceiver 625 receives instructions and reports test results of Chiplet1 via a port 630, for instance, which is coupled to the computer 360. The FPGA 320 operates as discussed in connection with FIG. 3 to receive instructions and report test results of Chiplet0 via the port 315, for instance, which is also coupled to the computer 360. In this case, the two chiplets communicate via electrical lines or path 671 in the package substrate 110 represented by an arrow. For example, the FPGA 620 can cause a signal to be input to Chiplet1 and from there to Chiplet0 while the FPGA 320 monitors the response of Chiplet0. If the inter-chiplet protocols of the chiplets are working properly, the FPGA 320 will receive an expected result. Otherwise, the FPGA 320 can conclude that an error has occurred in one or both chiplets. Similarly, the FPGA 620 can cause a signal to be input to Chiplet0 and from there to Chiplet1 while the FPGA 620 monitors the response of Chiplet1. If the inter-chiplet protocols of the chiplets are working properly, the FPGA 620 will receive an expected result. Otherwise, the FPGA 620 can conclude that an error has occurred in one or both chiplets.

The packages 305 and 605 are examples of first and second test circuits, respectively, for the chiplets, which are external to the chiplet package.

Generally, the second use case can be used when trying to design a leading edge process UCIe PHY which requires a way to test the PHY electrical and logical features. In other approaches, all UCIe PHY testing occurs using test pattern generators embedded inside the PHY. The solutions provided herein provide a way to push test pattern signals on the UCIe RDI without such an embedded test pattern generator. The solution involves pushing traffic on to a test chiplet without requiring a complete system in package.

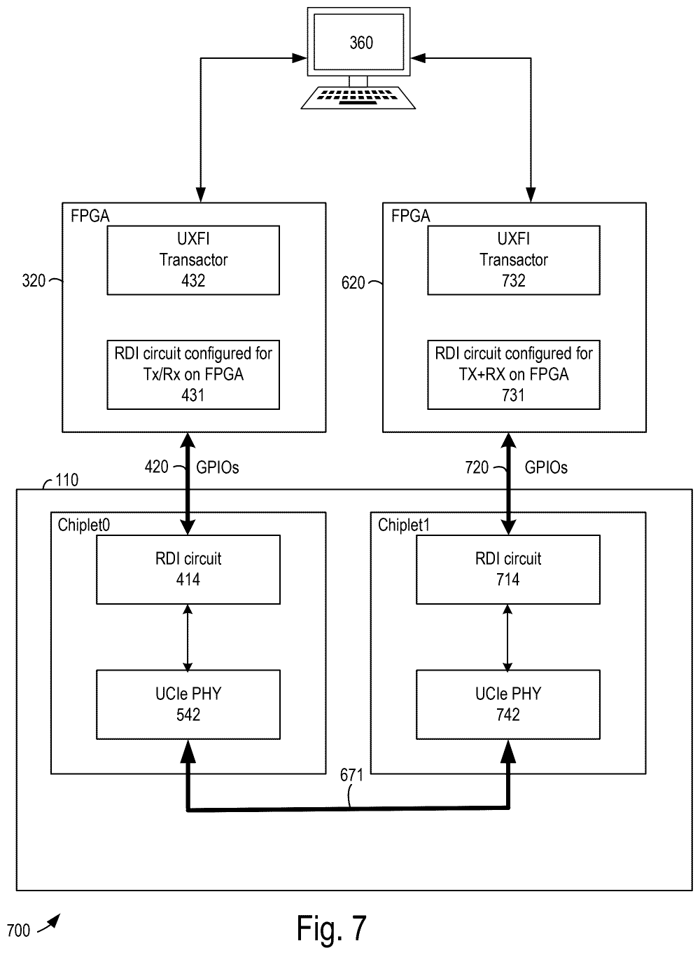

FIG. 7 depicts an example system 700 for the second use case, in accordance with various embodiments. The test setup includes Chiplet0 connected to Chiplet1 by the path 671, in a direct connection which may be part of the chiplet architecture. Chiplet0 includes the RDI circuit 414 (FIG. 4) coupled to the UCIe PHY circuit 542 (FIG. 5A). Chiplet1 includes respective copies of these circuits with an RDI circuit 714 coupled to a UCIe PHY circuit 742. Chiplet0 communicates via the GPIO interface 420 with the FPGA 320 as discussed in connection with FIG. 4A. Similarly, Chiplet1 communicates via a GPIO interface 720 with the FPGA 620 as discussed in connection with FIG. 6.

Chiplet2 further includes, in the FPGA 620, an RDI circuit 731 and UXFI transactor 732 corresponding to the RDI circuit 431 and UXFI transactor 432, respectively.

The path 671 can be a standard or advanced package interconnect under the UCIe standard, for example. The standard package (UCIe-S) is used for cost-effective performance and the advanced package (UCIe-A) is used for power-efficient performance.

In an example implementation, the system 700 includes a first chiplet Chiplet0 comprising a physical layer circuit 542 to perform inter-chiplet communications, and one or more interface circuits 414; a second chiplet Chiplet1 comprising a physical layer circuit 742 to perform the inter-chiplet communications with the first chiplet, and one or more interface circuits 714; a first external control circuit 320, external to the first chiplet; and a second external control circuit 620, external to the second chiplet, wherein: the first control circuit is configured to transmit test pattern signals to the first chiplet; the first chiplet is configured to transmit the test pattern signals to the second chiplet; and the second chiplet is configured to transmit the test pattern signals to the second external control circuit.

In one approach, the test pattern signals are first test pattern signals; the second control circuit is configured to transmit second test pattern signals to the second chiplet; the second chiplet is configured to transmit the second test pattern signals to the first chiplet; and the first chiplet is configured to transmit the second test pattern signals to the first external control circuit.

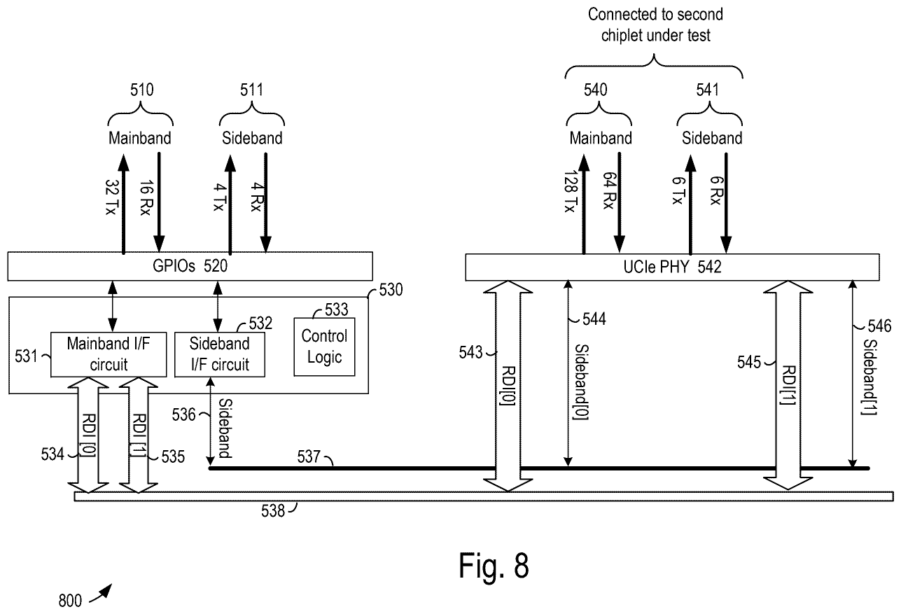

FIG. 8 depicts an example system 800 for the second use case, in accordance with various embodiments. The system 800 includes a subset of the components in FIGS. 5A and 5B. The multiplexers 550 and 560, sideband-to-UCIe circuit 570, D2D adapters 552 and 562, Protocol layer circuits 554 and 564, core circuits 580 and their associated paths as not present or used. The UCIe PHY 542 of Chiplet0 is active as depicted in FIG. 7 to communicate with the corresponding UCIe PHY of Chiplet1. Chiplet1 may have a circuit which is a copy of the system 800.

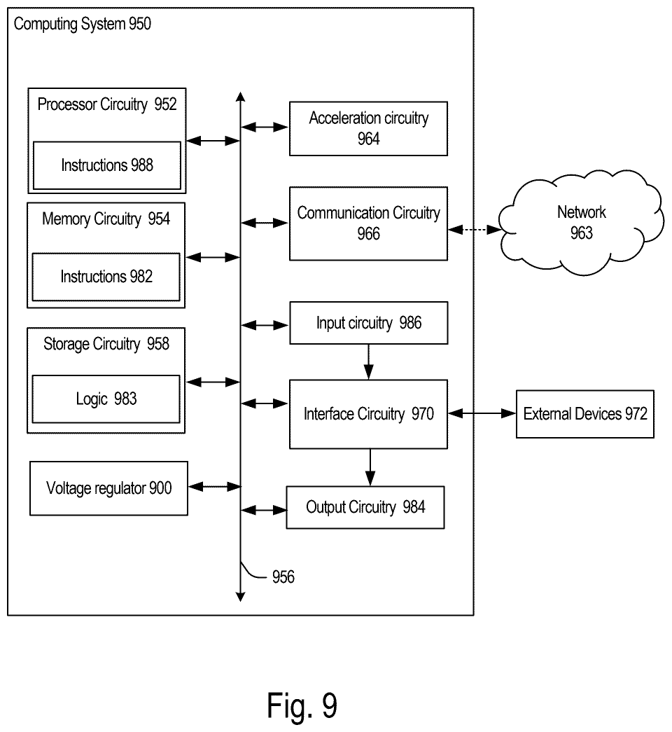

FIG. 9 illustrates an example of components that may be present in a computing system 950 for implementing the techniques (e.g., operations, processes, methods, and methodologies) described herein.

The computing system 950 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 950, or as components otherwise incorporated within a chassis of a larger system. In an example implementation, the chiplet packages are provided in any of the components 952, 954, 958, 900, 964, 966, 986, 970, 972 or 984. In one approach, all or part of the computing system 950 is provided in a SoP, System in Package (SiP) or a System on Chip (SoC).

The voltage regulator can provide a voltage Vout to one or more of the components of the computing system 950. The memory circuitry 954 may store instructions and the processor circuitry 952 may execute the instructions to perform the functions described herein.

The system 950 includes processor circuitry in the form of one or more processors 952. The processor circuitry 952 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 952 may include one or more hardware accelerators (e.g., same or similar to acceleration circuitry 964), which may be microprocessors, programmable processing devices (e.g., FPGA, ASIC, etc.), or the like. The one or more accelerators may include, for example, computer vision and/or deep learning accelerators. In some implementations, the processor circuitry 952 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein The processor circuitry 952 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 952 may be coupled with or may include memory/storage and may be configured to execute instructions stored in the memory/storage to enable various applications or operating systems to run on the platform 950. The processors (or cores) 1052 is configured to operate application software to provide a specific service to a user of the platform 1050. In some embodiments, the processor(s) 1052 may be a special-purpose processor(s)/controller(s) configured (or configurable) to operate according to the various embodiments herein.

As examples, the processor(s) 952 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc. ® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc. ; or the like. In some implementations, the processor(s) 952 may be a part of a system on a chip (SoC), System-in-Package (SiP), a multi-chip package (MCP), and/or the like, in which the processor(s) 952 and other components are formed into a single integrated circuit, or a single package, such as the Edison™ or Galileo™ SoC boards from Intel® Corporation. Other examples of the processor(s) 952 are mentioned elsewhere in the present disclosure.

The system 950 may include or be coupled to acceleration circuitry 964, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 964 may comprise logic blocks or logic fabric and other interconnected resources that may be programmed (configured) to perform various functions, such as the procedures, methods, functions, etc. of the various embodiments discussed herein. In such implementations, the acceleration circuitry 964 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 952 and/or acceleration circuitry 964 may include hardware elements specifically tailored for machine learning and/or artificial intelligence (AI) functionality. In these implementations, the processor circuitry 952 and/or acceleration circuitry 964 may be, or may include, an AI engine chip that can run many different kinds of AI instruction sets once loaded with the appropriate weightings and training code. Additionally or alternatively, the processor circuitry 952 and/or acceleration circuitry 964 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPs™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 952 and/or acceleration circuitry 964 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® A11 or A12 Bionic SoC, the Neural Processing Unit (NPU) within the HiSilicon Kirin provided by Huawei®, and/or the like. In some hardware-based implementations, individual subsystems of system 950 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 950 also includes system memory 954. Any number of memory devices may be used to provide for a given amount of system memory. As examples, the memory 954 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 954 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 954 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 958 provides persistent storage of information such as data, applications, operating systems and so forth. In an example, the storage 958 may be implemented via a solid-state disk drive (SSDD) and/or high-speed electrically erasable memory (commonly referred to as “flash memory”). Other devices that may be used for the storage 958 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 954 and/or storage circuitry 958 may also incorporate three-dimensional (3D) cross-point (XPOINT) memories from Intel® and Micron®.

The memory circuitry 954 and/or storage circuitry 958 is/are configured to store computational logic 983 in the form of software, firmware, microcode, or hardware-level instructions to implement the techniques described herein. The computational logic 983 may be employed to store working copies and/or permanent copies of programming instructions, or data to create the programming instructions, for the operation of various components of system 950 (e.g., drivers, libraries, application programming interfaces (APIs), etc.), an operating system of system 950, one or more applications, and/or for carrying out the embodiments discussed herein. The computational logic 983 may be stored or loaded into memory circuitry 954 as instructions 982, or data to create the instructions 982, which are then accessed for execution by the processor circuitry 952 to carry out the functions described herein. The processor circuitry 952 and/or the acceleration circuitry 964 accesses the memory circuitry 954 and/or the storage circuitry 958 over the interconnect (IX) 956. The instructions 982 direct the processor circuitry 952 to perform a specific sequence or flow of actions, for example, as described with respect to flowchart(s) and block diagram(s) of operations and functionality depicted previously. The various elements may be implemented by assembler instructions supported by processor circuitry 952 or high-level languages that may be compiled into instructions 988, or data to create the instructions 988, to be executed by the processor circuitry 952. The permanent copy of the programming instructions may be placed into persistent storage devices of storage circuitry 958 in the factory or in the field through, for example, a distribution medium (not shown), through a communication interface (e.g., from a distribution server (not shown)), over-the-air (OTA), or any combination thereof.

The IX 956 couples the processor 952 to communication circuitry 966 for communications with other devices, such as a remote server (not shown) and the like. The communication circuitry 966 is a hardware element, or collection of hardware elements, used to communicate over one or more networks 963 and/or with other devices. In one example, communication circuitry 966 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 966 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 956 also couples the processor 952 to interface circuitry 970 that is used to connect system 950 with one or more external devices 972. The external devices 972 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 950, which are referred to as input circuitry 986 and output circuitry 984. The input circuitry 986 and output circuitry 984 include one or more user interfaces designed to enable user interaction with the platform 950 and/or peripheral component interfaces designed to enable peripheral component interaction with the platform 950. Input circuitry 986 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 984 may be included to show information or otherwise convey information, such as sensor readings, actuator position(s), or other like information. Data and/or graphics may be displayed on one or more user interface components of the output circuitry 984. Output circuitry 984 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 950. The output circuitry 984 may also include speakers and/or other audio emitting devices, printer(s), and/or the like. Additionally or alternatively, sensor(s) may be used as the input circuitry 984 (e.g., an image capture device, motion capture device, or the like) and one or more actuators may be used as the output device circuitry 984 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 950 may communicate over the IX 956. The IX 956 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 956 may be a proprietary bus, for example, used in a SoC based system.

The number, capability, and/or capacity of the elements of system 950 may vary, depending on whether computing system 950 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 950 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

Some non-limiting examples of various embodiments are presented below.

Example 1 includes an apparatus, comprising: a chiplet having a physical layer circuit; one or more die-to-die adapters in the chiplet which are coupled to the physical layer circuit; one or more interface circuits in the chiplet coupled to the one or more die-to-die adapters, wherein the one or more interface circuits comprise a down conversion circuit and an up conversion circuit; and an external control circuit, external to the chiplet, and coupled to the one or more interface circuits.

Example 2 includes the apparatus of Example 1, wherein the one or more interface circuits are capable of receiving test pattern signals from the external control circuit, perform up conversion on the test pattern signals to provide up converted test pattern signals, and transmit the up converted test pattern signals to the one or more die-to-die adapters.

Example 3 includes the apparatus of Example 2, wherein the one or more interface circuits are capable of receiving response signals from the one or more die-to-die adapters, down convert the response signals to provide down converted response signals, and transmit the down converted response signals to the external control circuit.

Example 4 includes the apparatus of any one of Examples 1-3, wherein the external control circuit comprises a Field-Programmable Gate Array (FPGA).

Example 5 includes the apparatus of Example 4, wherein the chiplet is on a first package substrate on a circuit board and the FPGA is on a second package substrate on the circuit board.

Example 6 includes the apparatus of any one of Examples 1-5, further comprising one or more multiplexers coupled between the physical layer circuit and the one or more die-to-die adapters, wherein the one or more multiplexers are capable of receiving a selection signal which couples the one or more interface circuits but not the physical layer circuit to the one or more die-to-die adapters when the chiplet is under test by the external control circuit.

Example 7 includes the apparatus of any one of Examples 1-6, further comprising one or more multiplexers coupled between the physical layer circuit and the one or more die-to-die adapters, wherein the one or more multiplexers are capable of receiving a selection signal which couples the physical layer circuit but not the one or more interface circuits to the one or more die-to-die adapters when the chiplet is not under test by the external control circuit.

Example 8 includes the apparatus of any one of Examples 1-7, wherein the one or more die-to-die adapters are to communicate with the external control circuit via the one or more interface circuits to test a performance of an inter-chiplet communication of the one or more die-to-die adapters.

Example 9 includes the apparatus of Example 8, wherein the performance is tested relative to a Universal Chiplet Interconnect Express (UCIe) standard.

Example 10 includes the apparatus of any one of Examples 1-9, wherein the chiplet is provided in a System in Package in at least one of a processor, memory, storage, voltage regulator, acceleration circuitry, communication circuitry, input circuitry, interface circuitry, or output circuitry of a computing device.

Example 11 includes the apparatus of any one of Examples 1-10, wherein the chiplet comprises a protocol layer circuit coupled to the one or more die-to-die adapters, and the protocol layer circuit is to operate according to an inter-chiplet communication standard.

Example 12 includes a control circuit, comprising: a die-to-die interface circuit configured to transmit test pattern signals to, and receive corresponding responses from, a chiplet to test a performance of an inter-chiplet communication of the chiplet, wherein Example X includes the control circuit is external to the chiplet; and a transactor to translate the test pattern signals from a format compatible with software running on a computer to a format compatible with the chiplet, and to translate the responses from the format compatible with the chiplet to the format compatible with the computer.

Example 13 includes the control circuit of Example 12, wherein the chiplet is on a first package substrate on a circuit board and Example X includes the control circuit is on a second package substrate on the circuit board.

Example 14 includes the control circuit of Example 12 or 13, wherein the test signals are to test a performance of one or more die-to-die adapters in the chiplet, and the one or more die-to-die adapters operate at a higher frequency than Example X includes the control circuit.

Example 15 includes the control circuit of any one of Examples 12-14, wherein the test pattern signals comprise mainband and sideband signals.

Example 16 includes a system, comprising: a first chiplet comprising a physical layer circuit to perform inter-chiplet communications, and one or more interface circuits; a second chiplet comprising a physical layer circuit to perform the inter-chiplet communications with the first chiplet, and one or more interface circuits; a first external control circuit, external to the first chiplet; and a second external control circuit, external to the second chiplet, wherein: the first external control circuit is configured to transmit test pattern signals to the first chiplet; the first chiplet is configured to transmit the test pattern signals to the second chiplet; and the second chiplet is configured to transmit the test pattern signals to the second external control circuit.

Example 17 includes the system of Example 16, wherein the second external control circuit is configured to transmit the test pattern signals to the second external control circuit in response to which the second external control circuit is to determine whether an error occurred in the inter-chiplet communications.

Example 18 includes the system of Example 16 or 17, wherein the first and second chiplets are on a common package substrate, and first and second external control circuits are one or more other package substrates.

Example 19 includes the system of any one of Examples 16-18, wherein: the test pattern signals are first test pattern signals; the second control circuit is configured to transmit second test pattern signals to the second chiplet; the second chiplet is configured to transmit the second test pattern signals to the first chiplet; and the first chiplet is configured to transmit the second test pattern signals to the first external control circuit.

Example 20 includes the system of any one of Examples 16-19, wherein the first and second control circuits comprise respective Field-Programmable Gate Arrays (FPGAs).

Example 21 includes a method for testing a chiplet, comprising: receiving a test signal from an external control circuit at one or more interface circuits in the chiplet; upconverting a frequency of the test signal at the one or more interface circuits for use by one or more die-to-die adapters in the chiplet which are coupled to a physical layer circuit; receiving a response to the test signal at the one or more interface circuits from the one or more die-to-die adapters; and down converting a frequency of the response for use by the external control circuit.

Example 22 includes the method of Example 21, further comprising: providing a selection signal to one or more multiplexers coupled between the physical layer circuit and the one or more die-to-die adapters, wherein the selection signal couples the one or more interface circuits but not the physical layer circuit to the one or more die-to-die adapters when the chiplet is under test by the external control circuit.

Example 23 includes the method of Example 21 or 22, further comprising: providing a selection signal to one or more multiplexers coupled between the physical layer circuit and the one or more die-to-die adapters, wherein the selection signal couples the physical layer circuit but not the one or more interface circuits to the one or more die-to-die adapters when the chiplet is not under test by the external control circuit.

Example 24 includes an apparatus, comprising means to perform the method of any one of Examples 21-23.

Example 25 includes a machine-readable storage including machine-readable instructions which, when executed, cause a computer to implement the method of any one of Examples 21-23.

Example 26 includes a computer program comprising instructions which, when executed by a computer, cause the computer to carry out the method of any one of Examples 21-23.

Example 26 includes a method of manufacturing a control circuit, comprising: using a die-to-die interface circuit configured to transmit test pattern signals to, and receive corresponding responses from, a chiplet to test a performance of an inter-chiplet communication of the chiplet, wherein the control circuit is external to the chiplet; and using a transactor to translate the test pattern signals from a format compatible with software running on a computer to a format compatible with the chiplet, and to translate the responses from the format compatible with the chiplet to the format compatible with the computer.

Example 27 includes the method of Example 26, wherein the chiplet is on a first package substrate on a circuit board and the control circuit is on a second package substrate on the circuit board.

Example 28 includes the method of Example 26 or 27, further comprising using the test signals to test a performance of one or more die-to-die adapters in the chiplet, and operating the one or more die-to-die adapters at a higher frequency than the control circuit.

Example 29 includes the method of any one of Examples 26-28, wherein the test pattern signals comprise mainband and sideband signals.

Example 30 includes an apparatus, comprising means to perform the method of any one of Examples 26-28.

Example 31 includes a machine-readable storage including machine-readable instructions which, when executed, cause a computer to implement the method of any one of Examples 26-28.

Example 32 includes a computer program comprising instructions which, when executed by a computer, cause the computer to carry out the method of any one of Examples 26-28.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C”means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus, comprising:
a chiplet having a physical layer circuit;
one or more die-to-die adapters in the chiplet coupled to the physical layer circuit;
one or more interface circuits in the chiplet coupled to the one or more die-to-die adapters, wherein the one or more interface circuits comprise a down conversion circuit and an up conversion circuit; and
an external control circuit, external to the chiplet, and coupled to the one or more interface circuits.

2. The apparatus of claim 1, wherein the one or more interface circuits are capable of receiving receive test pattern signals from the external control circuit, perform up conversion on the test pattern signals to provide up converted test pattern signals, and transmit the up converted test pattern signals to the one or more die-to-die adapters.

3. The apparatus of claim 2, wherein the one or more interface circuits are capable of receiving response signals from the one or more die-to-die adapters, down convert the response signals to provide down converted response signals, and transmit the down converted response signals to the external control circuit.

4. The apparatus of claim 1, wherein the external control circuit comprises a Field-Programmable Gate Array (FPGA).

5. The apparatus of claim 4, wherein the chiplet is on a first package substrate on a circuit board and the FPGA is on a second package substrate on the circuit board.

6. The apparatus of claim 1, further comprising one or more multiplexers coupled between the physical layer circuit and the one or more die-to-die adapters, wherein the one or more multiplexers are capable of receiving a selection signal which couples the one or more interface circuits but not the physical layer circuit to the one or more die-to-die adapters when the chiplet is under test by the external control circuit.

7. The apparatus of claim 1, further comprising one or more multiplexers coupled between the physical layer circuit and the one or more die-to-die adapters, wherein the one or more multiplexers are capable of receiving a selection signal which couples the physical layer circuit but not the one or more interface circuits to the one or more die-to-die adapters when the chiplet is not under test by the external control circuit.

8. The apparatus of claim 1, wherein the one or more die-to-die adapters are to communicate with the external control circuit via the one or more interface circuits to test a performance of an inter-chiplet communication of the one or more die-to-die adapters.

9. The apparatus of claim 8, wherein the performance is tested relative to a Universal Chiplet Interconnect Express (UCIe) standard.

10. The apparatus of claim 1, wherein the chiplet is provided in a System in Package in at least one of a processor, memory, storage, voltage regulator, acceleration circuitry, communication circuitry, input circuitry, interface circuitry, or output circuitry of a computing device.

11. The apparatus of claim 1, wherein the chiplet comprises a protocol layer circuit coupled to the one or more die-to-die adapters, and the protocol layer circuit is to operate according to an inter-chiplet communication standard.

12. A method of manufacturing a control circuit, comprising:
using a die-to-die interface circuit configured to transmit test pattern signals to, and receive corresponding responses from, a chiplet to test a performance of an inter-chiplet communication of the chiplet, wherein the control circuit is external to the chiplet; and
using a transactor to translate the test pattern signals from a format compatible with software running on a computer to a format compatible with the chiplet, and to translate the responses from the format compatible with the chiplet to the format compatible with the computer.

13. The method of claim 12, wherein the chiplet is on a first package substrate on a circuit board and the control circuit is on a second package substrate on the circuit board.

14. The method of claim 12, further comprising using the test signals to test a performance of one or more die-to-die adapters in the chiplet, and operating the one or more die-to-die adapters at a higher frequency than the control circuit.

15. The method of claim 12, wherein the test pattern signals comprise mainband and sideband signals.

16. A system, comprising:
a first chiplet comprising a physical layer circuit to perform inter-chiplet communications, and one or more interface circuits;
a second chiplet comprising a physical layer circuit to perform the inter-chiplet communications with the first chiplet, and one or more interface circuits;
a first external control circuit, external to the first chiplet; and
a second external control circuit, external to the second chiplet, wherein:
the first external control circuit is configured to transmit test pattern signals to the first chiplet;
the first chiplet is configured to transmit the test pattern signals to the second chiplet; and
the second chiplet is configured to transmit the test pattern signals to the second external control circuit.

17. The system of claim 16, wherein the second external control circuit is configured to transmit the test pattern signals to the second external control circuit in response to which the second external control circuit is to determine whether an error occurred in the inter-chiplet communications.

18. The system of claim 16, wherein the first and second chiplets are on a common package substrate, and first and second external control circuits are one or more other package substrates.

19. The system of claim 16, wherein:
the test pattern signals are first test pattern signals;
the second control circuit is configured to transmit second test pattern signals to the second chiplet;
the second chiplet is configured to transmit the second test pattern signals to the first chiplet; and
the first chiplet is configured to transmit the second test pattern signals to the first external control circuit.

20. The system of claim 16, wherein the first and second control circuits comprise respective Field-Programmable Gate Arrays (FPGAs).
